(19) United States
(12) Patent Application Publication
(10) Pub. No.: US 2004/0219774 A1
(43) Pub. Date: Nov. 4, 2004

(54) Method for forming conductive bump and device formed with such a conductive bump

(76) Inventor: Yu-Nung Shen, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/833,150

(22) Filed: Apr. 28, 2004

(30) Foreign Application Priority Data
May 2, 2003 (TW) 92112165

(51) Int. Cl. H01L 21/44

(52) U.S. Cl. 438/612

(57) ABSTRACT

A device formed with a conductive bump includes a semiconductor die having a pad-mounting surface and a plurality of bonding pads disposed on the pad-mounting surface, a plurality of bumps formed on the respective bonding pads, and a plurality of metallic layers formed on the respective bumps. Each of the metallic layers extends from a corresponding one of the bumps to a corresponding one of the bonding pads.

### BACKGROUND OF THE INVENTION

1. Field of the Invention

The present invention relates to method for forming a conductive bump, and particularly relates to a method for forming conductive bump and a device formed with such a conductive bump.

2. Background of the Invention

For environmental reasons, lead-free conductive material or conductive material of low -lead-contained content is used gradually and broadly instead of those of high lead-contained content.

Furthermore, a BGA type semiconductor package includes a plurality of solder balls arranged in an array on a ball-mounting surface of a package substrate, and the solder balls cannot meet the environmental requirements, either.

Hence, an improvement over the prior art is required to overcome the disadvantages thereof.

### SUMMARY OF INVENTION

The object of the invention is therefore to specify a method for forming a conductive bump and a device formed with such a conductive bump that can solve the problems mentioned above.

According to the invention, the object is achieved by a method for providing a conductive bump, and the method provides a semiconductor die having a pad-mounting surface and a plurality of bonding pads disposed on the pad-mounting surface. An insulation layer made of photoresist material is formed on the pad-mounting surface of the semiconductor die. The insulation layer is patterned and etched so as to form a plurality of through holes for exposing the respective bonding pads. A cover layer is formed over the insulation layer to hide the through holes. The cover layer is patterned and etched so as to form a plurality of exposure holes, which expose the respective bonding pads, and which are smaller than the through holes, respectively. The exposure holes are filled with bump-forming material so as to form bumps on the respective bonding pads. Each of the bumps is plated with a metallic layer after the cover layer is removed. Each of the metallic layers extends from the respective one of the bumps to the respective one of the bonding pads.

According to the invention, the object is achieved by a method for forming a conductive bump, and the method provides a semiconductor die with a pad-mounting surface and a plurality of bonding pads disposed on the pad-mounting surface. An insulation layer made of photoresist material is formed on and covers the pad-mounting surface of the semiconductor die. The insulation layer is patterned and etched so as to form a plurality of through holes for exposing the respective bonding pads. A plurality of photoresist layers are formed in the through holes and at the same height as the insulation layer. The plurality of photoresist layers are patterned and etched so as to form a plurality of exposure holes for exposing the respective bonding pads. The exposure holes are smaller than the through holes. The exposure holes in the photoresist layers are respectively filled with bump-forming material so as to form a plurality of bumps on the respective bonding pads. A metallic layer is formed on each of the bumps after the insulation layer is removed. Each of the metallic layers extends from a corresponding one of the bumps to a corresponding one of the bonding pads.

According to the invention, the object is achieved by a method for forming a conductive bump, and the method provides a semiconductor die with a pad-mounting surface and a plurality of bonding pads disposed on the pad-mounting surface. The pad-mounting surface of the semiconductor die is covered with an insulation layer made of photoresist material. The insulation layer is patterned and etched so as to form a plurality of through holes for exposing the respective bonding pads. The through holes of the insulation layer are filled with bump-forming material, such that a plurality of bumps of the bump-forming material are formed on the respective bonding pads. The insulation layer is removed, and a cover layer of photoresist material is formed on the pad-mounting surface of the semiconductor die to hide the bumps in the through holes. The cover layer is patterned and etched so as to form a plurality of openings for exposing the respective bumps. Each of the bumps is plated with a metallic layer after the cover layer is removed. The metallic layer on each of the bumps extends from the corresponding one of the bumps to the corresponding one of the bonding pads.

According to the invention, the object is achieved by a method for forming a conductive bump, and the method provides a semiconductor die with a pad-mounting surface and a plurality of bonding pads disposed on the pad-mounting surface. The pad-mounting surface of the semiconductor die is covered with an insulation layer made of photoresist material. The insulation layer is patterned and etched so as to form a plurality of through holes for exposing the respective bonding pads. The through holes of the insulation layer are filled with bump-forming material, such that a plurality of bumps of the bump-forming material are formed on the respective bonding pads. The insulation layer is removed and each of the bumps is plated with a metallic layer after the insulation layer is removed. The metallic layer on each of the bumps extends from a corresponding one of the bumps to a corresponding one of the bonding pads.

According to the invention, the object is achieved by a method for forming an conductive bump, and the method provides a semiconductor die with a pad-mounting surface and a plurality of bonding pads disposed on the pad-mounting surface. The pad-mounting surface of the semiconductor die is covered with a bump-forming layer made of photoresist material. The bump-forming layer is patterned and etched so as to form a plurality of bumps on the respective bonding pads. Each of the bumps is plated with a metallic layer. The metallic layer on each of the bumps extends from a corresponding one of the bumps to a corresponding one of the bonding pads.

According to the invention, the object is achieved by a method for forming a conductive bump, and the method provides a semiconductor die with a pad-mounting surface and a plurality of bonding pads disposed on the pad-mounting surface. The pad-mounting surface of a semiconductor die is covered with a bump-forming layer made of photoresist material. The bump-forming layer is patterned and etched so as to form a plurality of bumps on the respective bonding pads. An insulation layer made of photoresist material is formed on the pad-mounting surface of the semiconductor die to hide the bumps. The insulation layer is patterned and etched so as to form a plurality of through holes for exposing the respective bumps. Each of the bumps is plated with a metallic layer. The metallic layer on each of the bumps extends from a corresponding one of the bumps to a corresponding one of the bonding pads.

According to the invention, the object is achieved by a method for forming a conductive bump, and the method provides a package substrate that has a die-mounting surface, and a layout surface opposite to the die-mounting surface and having a plurality of contacts arranged thereon in an array. The contacts are connected electrically to the respective bonding pads of the semiconductor die to be mounted on the die-mounting surface. An insulation layer made of photoresist material is formed on the layout surface of package substrate. The insulation layer is patterned and etched so as to form a plurality of through holes for exposing the respective contacts. The through holes of the insulation layer are filled with bump-forming material so as to form a plurality of bumps on the respective contacts. Each of the bumps is plated with a metallic layer after the insulation layer is removed. The metallic layer on each of the bumps extends from a corresponding one of the bumps to a corresponding one of the contacts.

According to the invention, the object is achieved by a method for forming a conductive bump, and the method provides a package substrate that has a die-mounting surface, and a layout surface opposite to the die-mounting surface and having a plurality of contacts arranged thereon in an array. The contacts are connected electrically to the respective bonding pads of the semiconductor die to be mounted on the die-mounting surface. A bump-forming layer made of photoresist material is formed on the layout surface of package substrate. The bump-forming layer is patterned and etched so as to a plurality of bumps on the respective contacts. Each of the bumps is plated with a metallic layer. The metallic layer on each of the bumps extends from a corresponding one of the bumps to a corresponding one of the contacts.

According to the invention, the object is achieved by a method for providing a conductive bump, and the method provides a package substrate that has a die-mounting surface, and a layout surface opposite to the die-mounting surface and having a plurality of contacts arranged thereon in an array. The contacts are connected electrically to the respective bonding pads of the semiconductor die to be mounted on the die-mounting surface. A plurality of bumps is formed from conductive pastes on the respective contacts of the package substrate by a printing process using a stencil. Each of the bumps is plated with a metallic layer. The metallic layer on each of the bumps extends from a corresponding one of the bumps to a corresponding one of the contacts.

According to the invention, the object is achieved by a device formed with a conductive bump. The device includes a semiconductor die having a pad-mounting surface and a plurality of bonding pads disposed on the pad-mounting surface, a plurality of bumps formed on the respective bonding pads, and a plurality of metallic layers extending from a corresponding one of the bumps to a corresponding one of the bonding pads.

According to the invention, the object is achieved by a device formed with a conductive bump. The device includes a semiconductor die having a pad-mounting surface and a plurality of bonding pads disposed on the pad-mounting surface, a plurality of bumps formed on the respective bonding pads, and a plurality of metallic layers extending from a corresponding one of the bumps to a corresponding one of the bonding pads.

According to the invention, the object is achieved by a device formed with a conductive bump. The device includes a package substrate having a die-mounting surface, and a layout surface opposite to the die-mounting surface and having a plurality of contacts arranged on the layout surface in an array, a plurality of bumps formed on the respective contacts, and a plurality of metallic layers extending from a corresponding one of the bumps to a corresponding one of the contacts.

To provide a further understanding of the invention, the following detailed description illustrates embodiments and examples of the invention. Examples of the more important features of the invention thus are summarized rather broadly in order that the detailed description thereof that follows may be better understood, and in order that the contributions to the art may be appreciated. There are, of course, additional features of the invention that will be described hereinafter and which will form the subject of the claims appended hereto.

### BRIEF DESCRIPTION OF THE DRAWINGS

These and other features, aspects, and advantages of the present invention will become better understood with regard to the following description, appended claims, and accompanying drawings, where:

FIGS. 1 to 8 are cross-sectional views illustrating a first method according to the present invention;

FIGS. 9 to 16 are cross-sectional views illustrating a second method according to the present invention;

FIGS. 17 to 23 are cross-sectional views illustrating a third method according to the present invention;

FIGS. 24 to 29 are cross-sectional views illustrating a fourth method according to the present invention;

FIGS. 30 to 33 are cross-sectional views illustrating a fifth method according to the present invention;

FIGS. 34 to 38 are cross-sectional views illustrating a sixth method according to the present invention;

FIGS. 39 to 42 are cross-sectional views illustrating a seventh method according to the present invention;

FIGS. 43 to 48 are cross-sectional views illustrating a eighth method according to the present invention;

FIGS. 49 to 51 are cross-sectional views illustrating a ninth method according to the present invention; and

FIGS. 52 to 54 are cross-sectional views illustrating a tenth method according to the present invention.

### DETAILED DESCRIPTION OF THE EMBODIMENTS

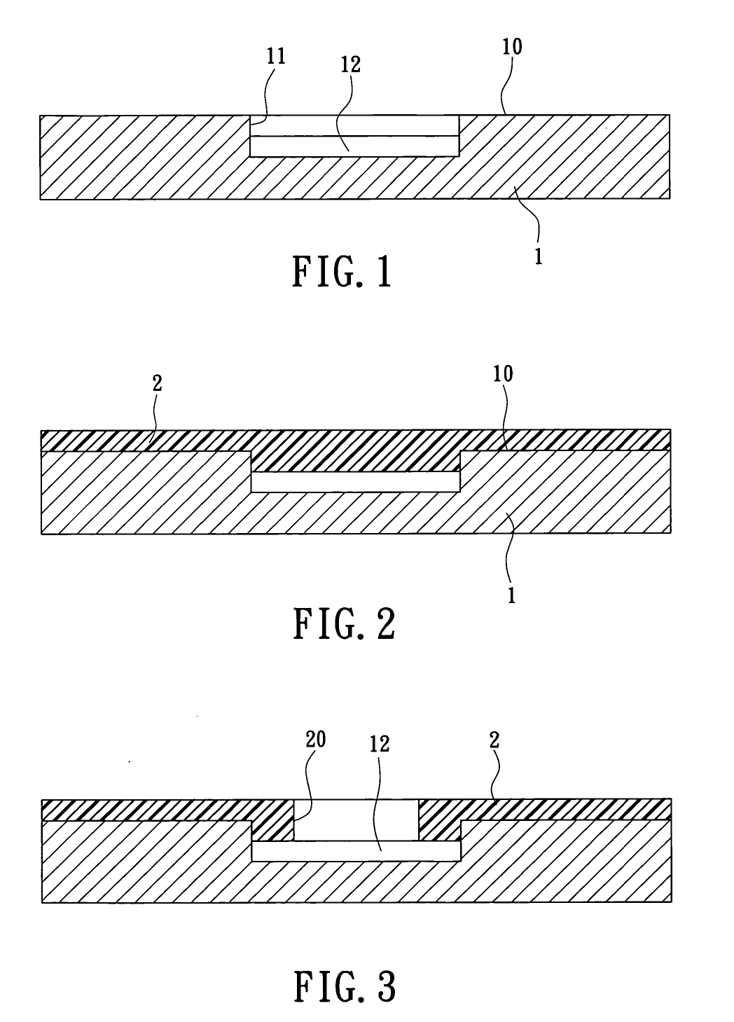

FIGS. 1 to 8 are cross-sectional views illustrating a first method according to the present invention to show a bump formed on a device having a semiconductor die.

Referring FIG. 1, a semiconductor die 1 is provided first. The semiconductor die 1 has a pad-mounting surface 10 and a plurality of bonding pads 11 disposed on the pad-mounting surface 10. FIG. 1 shows only a single bonding pad 11. The semiconductor die 1 can be a die diced from a wafer (not shown) or can be one of the dies of the wafer that has not diced. Each of the bonding pads 11 has an electroplated layer 12 formed thereon by plating.

The pad-mounting surface 10 of the semiconductor die 1 is covered with an insulation layer 2, as illustrated in FIG. 2.

In this embodiment, the insulation layer 2 is made of photoresist material, such as photo ink material, polyimide material, or the like.

Following the step of forming the insulation layer 2, the insulation layer 2 is patterned and etched so as to form a plurality of through holes 20 (in FIG. 3) for exposing the respective electroplated layers 12.

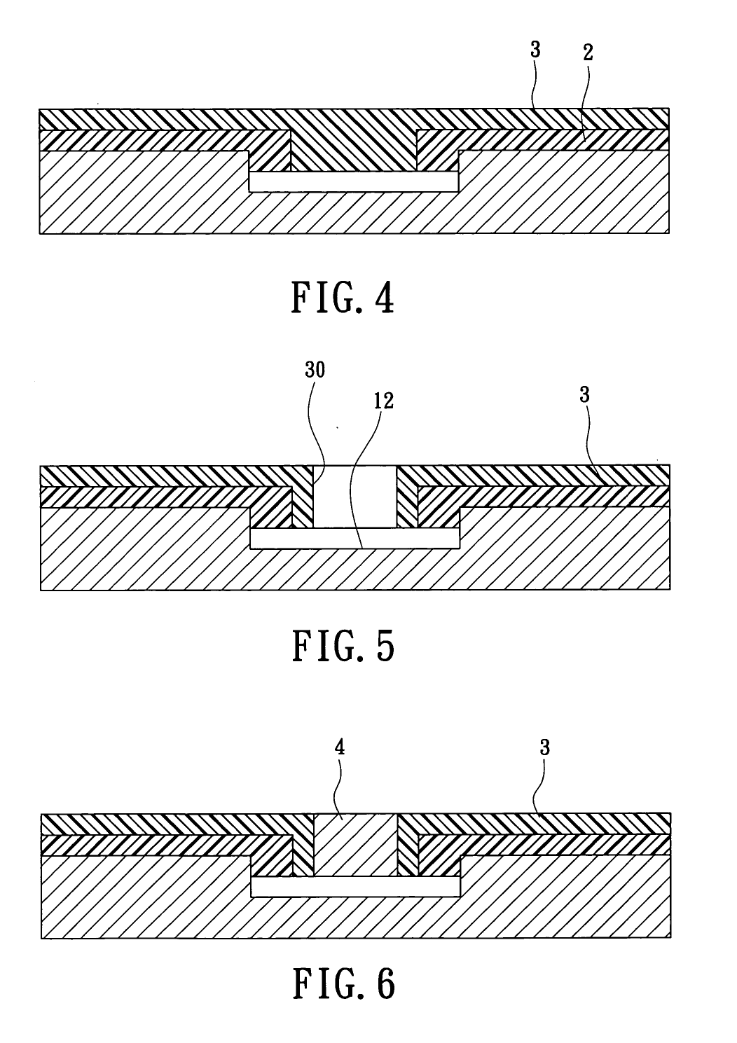

Next, a cover layer 3 is formed over the insulation layer 2 to hide the through holes 20 in FIG. 4, and is patterned and etched so as to form a plurality of exposure holes 30 (in FIG. 5), which expose the respective electroplated layers 12 and which are smaller than the respective through holes 20.

Referring to FIG. 6, the exposure holes 30 are then filled with bump-forming materials 4 to form a plurality of bumps on the respective electroplated layers 12.

The bump-forming material 4 can be conductive material like conductive paste or lead-free solder pastes, or nonconductive material like plastic material. In this embodiment, the bump-forming material 4 is conductive paste that has conductive metallic powders having at least one of gold, silver, copper, aluminum powders, etc.

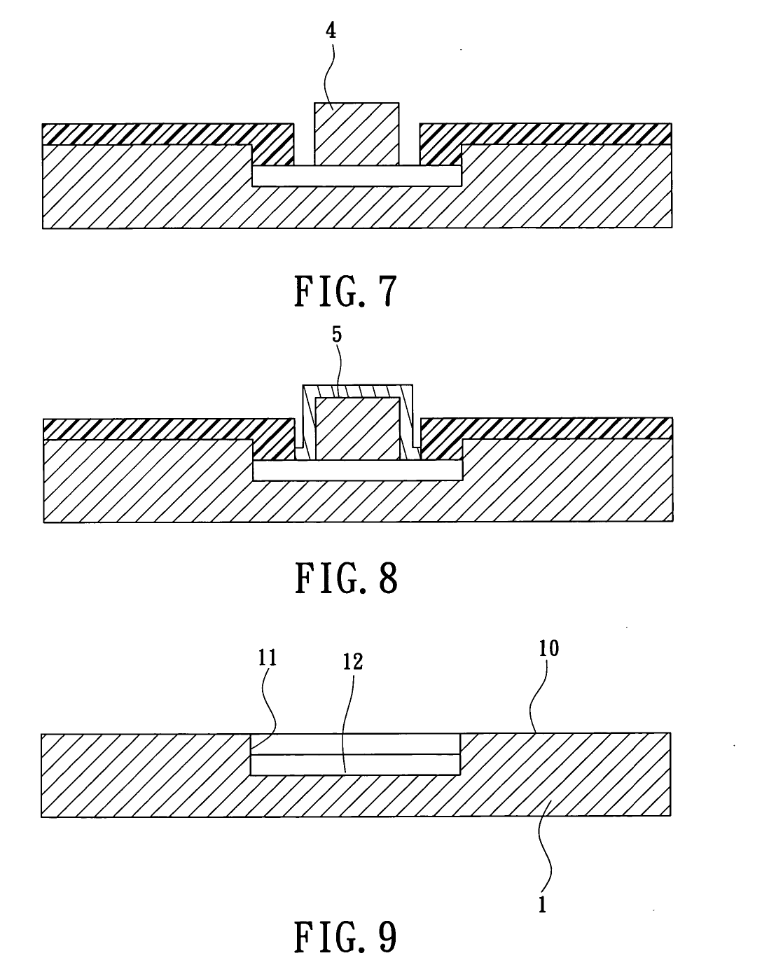

With respect to FIGS. 7 and 8, after the cover layer 3 is removed, a metallic layer 5 is formed on each of the bumps 4. The metallic layer 5 on each of the bumps extends from a corresponding one of the bumps 4 to a corresponding one of the electroplated layers 12.

FIGS. 9 to 16 are cross-sectional views illustrating a second method according to the present invention to show a bump formed on a device having a semiconductor die.

Referring to FIG. 9, as the second method, a semiconductor die 1 is provided first. The semiconductor die 1 has a pad-mounting surface 10 and a plurality of bonding pads 11 disposed on the pad-mounting surface 10. FIG. 9 shows only a single bonding pad 11. The semiconductor die 1 can be a die diced from a wafer (not shown) or can be one of the semiconductor dies of the wafer that has not been diced. Each of the bonding pads 11 has an electroplated layer 12 formed thereon by plating.

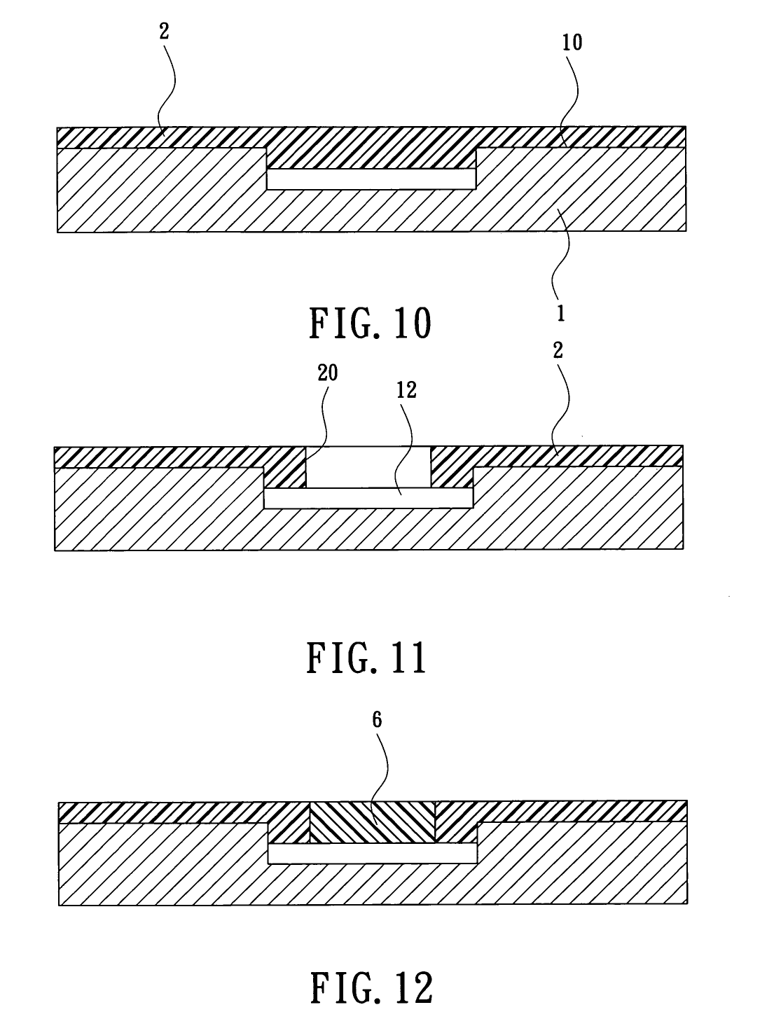

As in the first method, the pad-mounting surface 10 of the semiconductor die 1 is covered with an insulation layer 2, as illustrated in FIG. 10.

The insulation layer 2 is patterned and etched so as to form a plurality of through holes 20 (in FIG. 11) for exposing the respective electroplated layers 12.

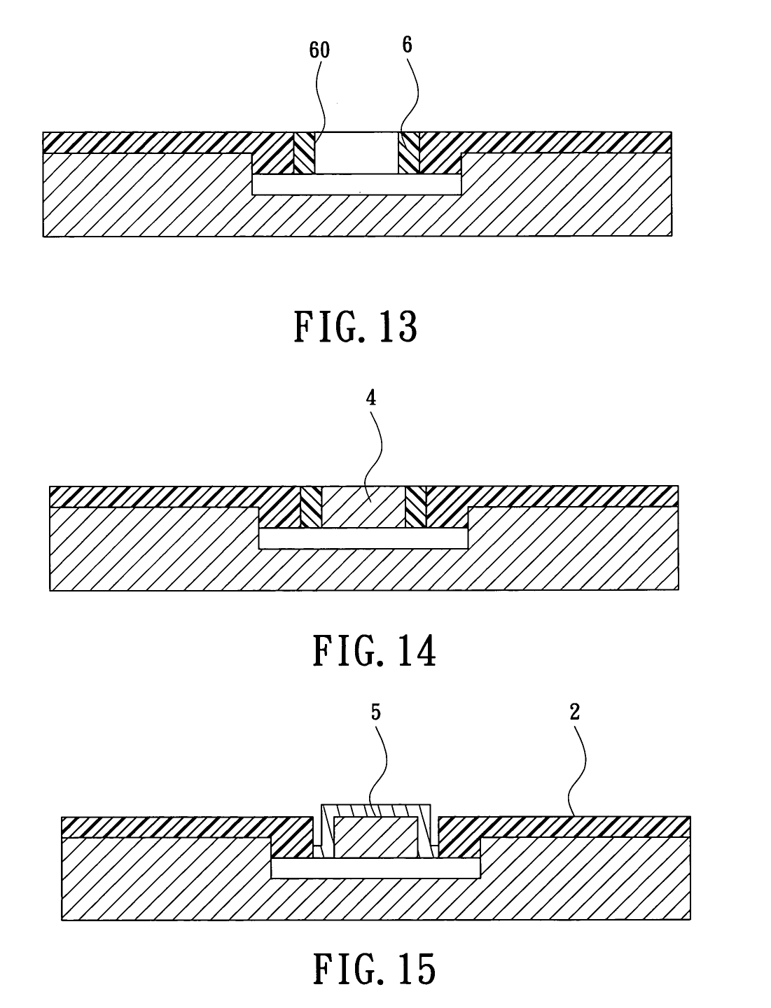

After that, in each of the through holes 20, a photoresist layer 6 (in FIG. 12) having the same height as the insulation layer 2 is formed. With respect to FIG. 13, the photoresist layer 6 is patterned and etched so as to form an exposure hole 60 for exposing the corresponding electroplated layer 12.

In particular, the exposure hole 60 is smaller than each of the through holes 20.

After the exposure hole 60 is formed, the exposure hole 60 is filled with bump-forming material 4 in FIG. 14 to form a bump on the electroplated layer 12.

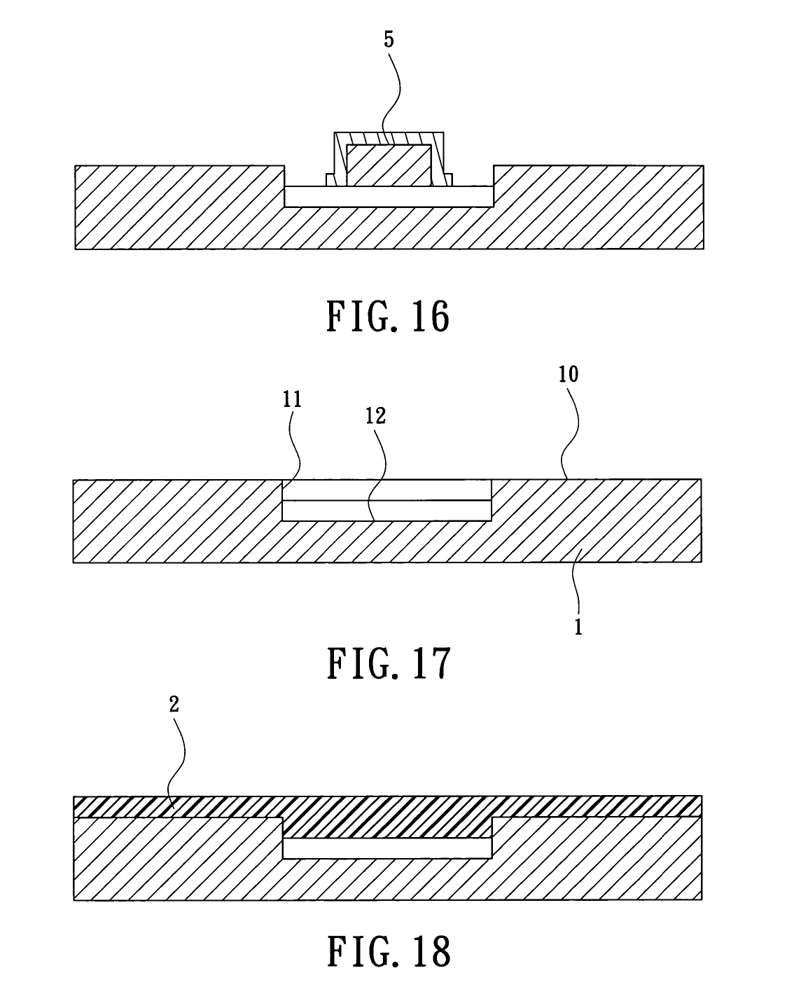

With respect to FIGS. 15 and 16, after the photoresist layer 6 is removed, a metallic layer 5 is formed on each of the bumps 4. The metallic layer 5 on each of the bumps 4 extends from a corresponding one of the bumps 4 to a corresponding one of the electroplated layers 12. The insulation layer 2 is finally removed.

FIGS. 17 to 23 are cross-sectional views illustrating a third method according to the present invention to show a bump formed on a device having a semiconductor die.

Referring to FIG. 17, as the third method, a semiconductor die 1 is provided first. The semiconductor die 1 has a pad-mounting surface 10 and a plurality of bonding pads 11 disposed on the pad-mounting surface 10. FIG. 17 shows only a single bonding pad 11. Each of the bonding pads 11 has an electroplated layer 12 formed thereon by plating.

As in the first method, the pad-mounting surface 10 of the semiconductor die 1 is covered with an insulation layer 2, as illustrated in FIG. 18.

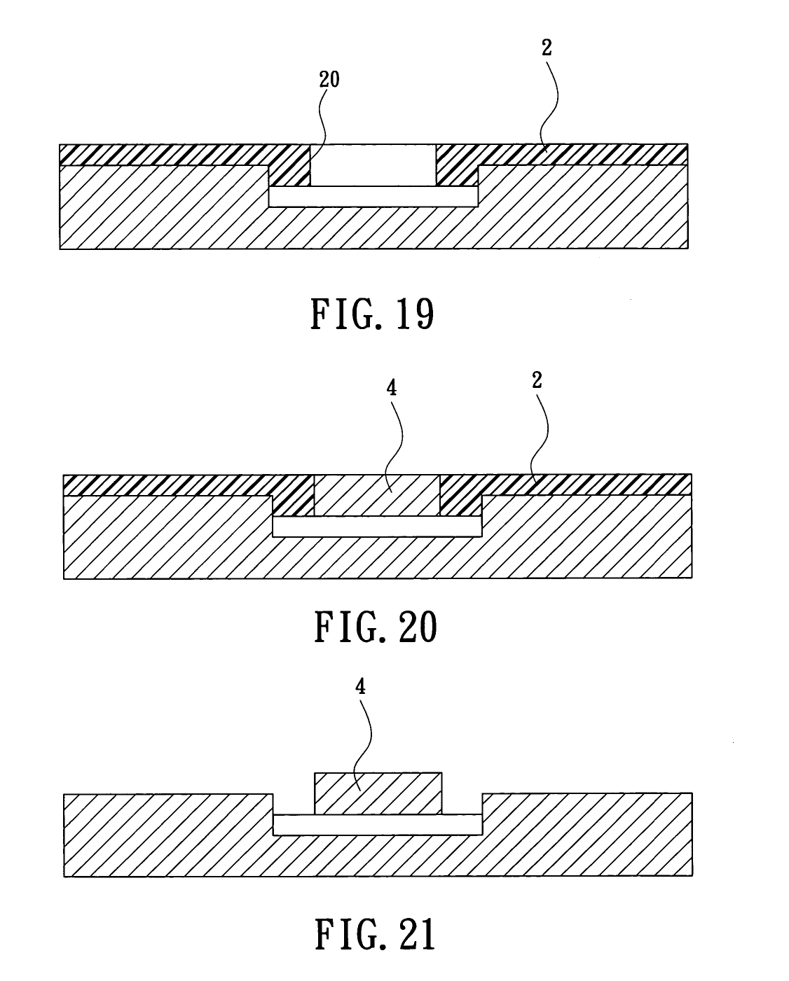

The insulation layer 2 is patterned and etched so as to form a plurality of through holes 20 (in FIG. 19) for exposing the respective electroplated layers 12.

The through holes 20 of the insulation layer 2 are then filled with bump-forming material 4 as shown in FIG. 20, such that a plurality of bumps 4 of the bump-forming material are formed on the respective electroplated layers 12.

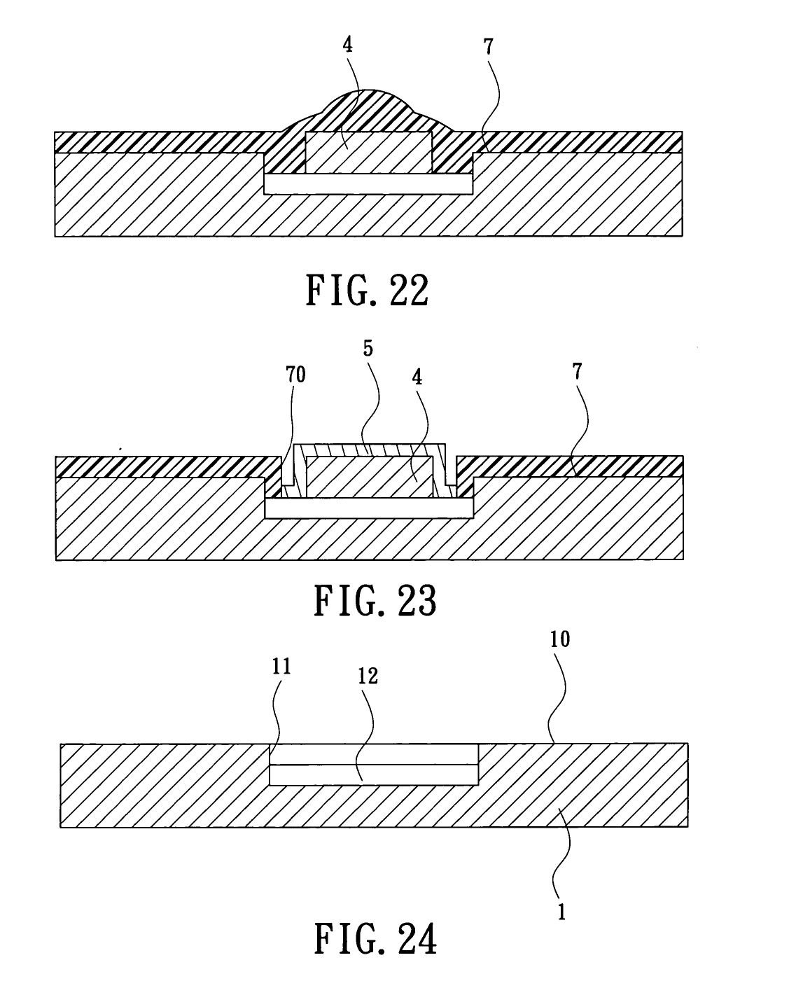

The insulation layer 2 illustrated in FIG. 21 is removed then. The pad-mounting surface 10 of the semiconductor die 1 is covered (in FIG. 22) with a cover layer 7 that is made of photoresist material to hide the bumps 4.

The cover layer 7 is patterned and etched so as to form a plurality of openings 70 for exposing the respective bumps 4 (in FIG. 23). On each of the bumps 4, a metallic layer 5 is formed. The metallic layer 5 on each of the bumps 4 extends from a corresponding one of the bumps 4 to a corresponding one of the electroplated layers 12.

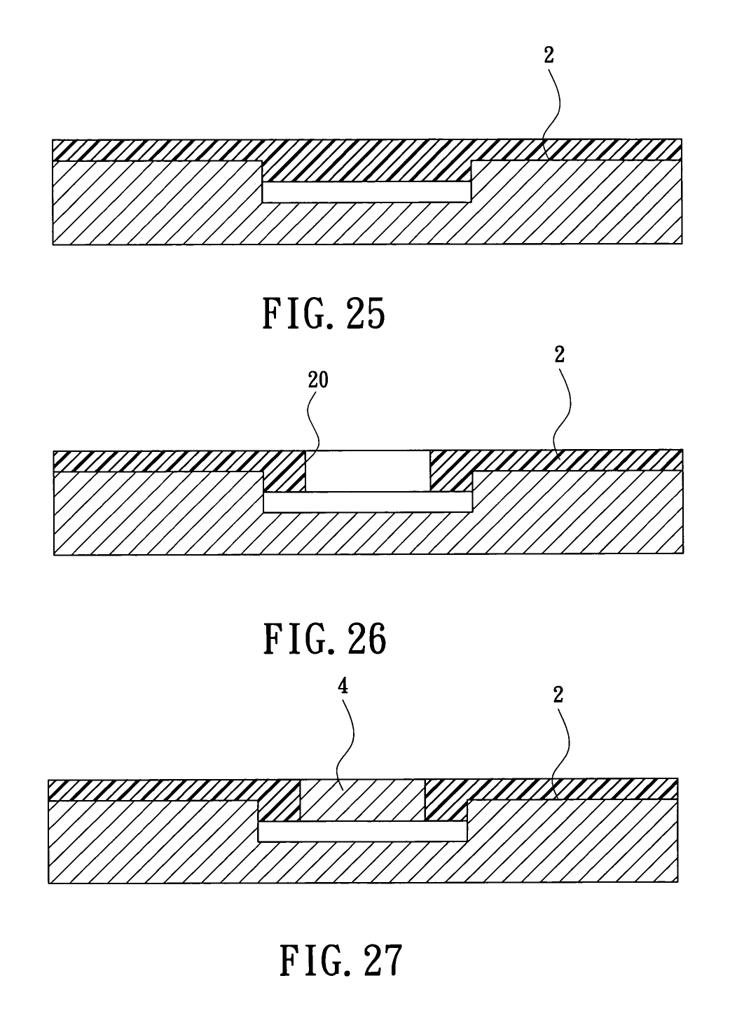

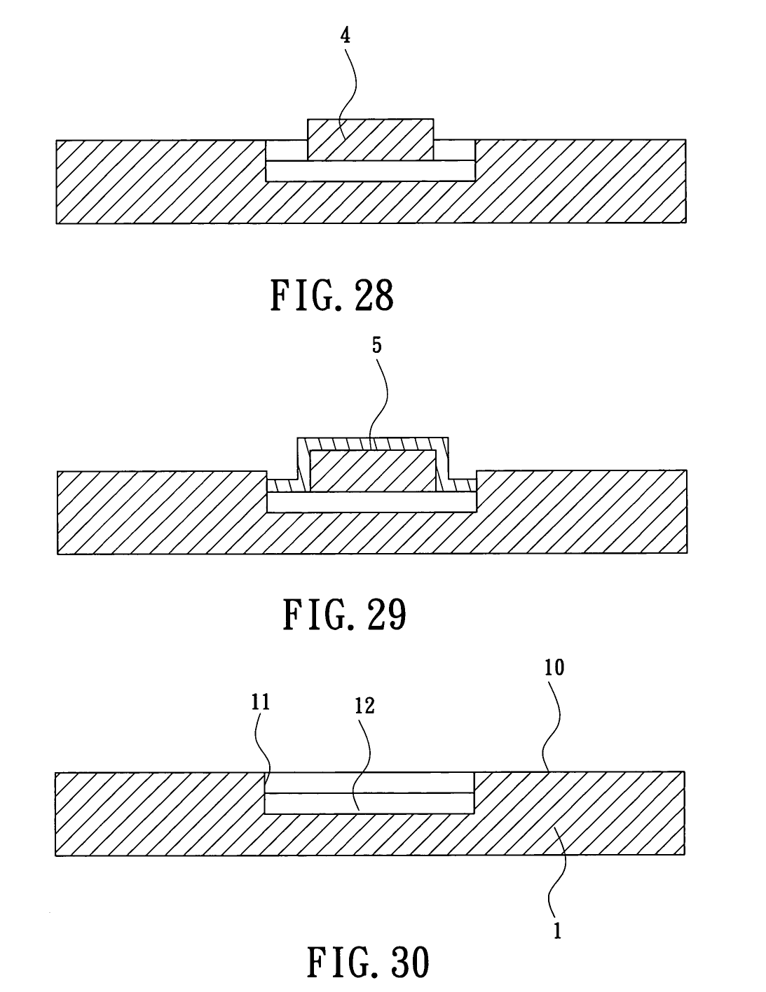

FIGS. 24 to 29 are cross-sectional views illustrating a fourth method according to the present invention to show a bump formed on a device having a semiconductor die.

The process in FIGS. 24 to 28 is omitted, as it is the same as that described in conjunction with FIGS. 17 to 21 according to the third method.

The fourth method differs from the third method in that the formation of the cover layer is eliminated after the insulation layer 2 is removed. Referring to FIG. 29, after the insulation 2 is removed, each of the bumps 4 is plated with a metallic layer 5, and the metallic layer 5 on each of the bumps 4 extends from a corresponding one of the bumps 4 to a corresponding one of the electroplated layers 12.

FIGS. 30 to 33 are cross-sectional views illustrating a fifth method according to the present invention to show a bump formed on a device having a semiconductor die.

Referring to FIG. 30, a semiconductor die 1 is provided first. The semiconductor die 1 has a pad-mounting surface 10 and a plurality of bonding pads 11 disposed on the pad-mounting surface 10. FIG. 30 shows only a single bonding pad 11. Each of the bonding pads 11 has an electroplated layer 12 formed thereon by plating.

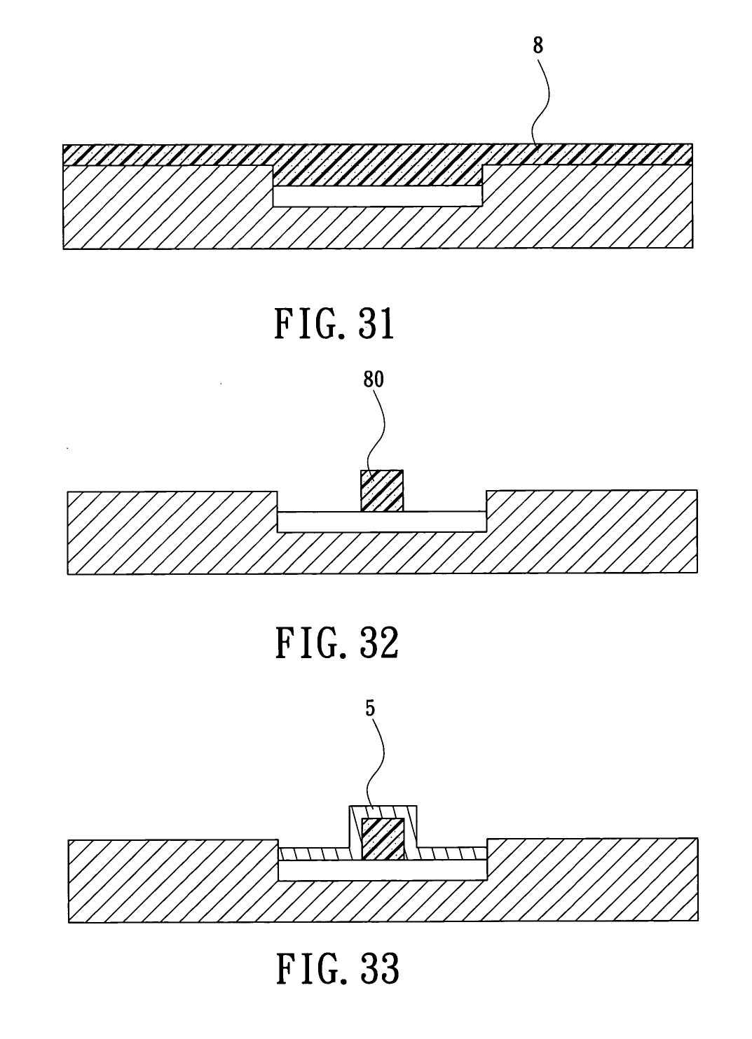

A bump-forming layer 8 is formed on the pad-mounting surface 10 of the semiconductor die 1 as illustrated in FIG. 31. The bump-forming layer 8 is made of photoresist material or photoresist material having low-valence metallic powders having at least one of gold, silver, copper, iron, or aluminum powders, plastic material, or graphite material contained therein.

The bump-forming layer 8 is then patterned and etched so as to form a plurality of bumps 80 (in FIG. 32) on respective electroplated layers 12.

Each of the bumps 80 is plated with a metallic layer 5. The metallic layer 5 on each of the bumps extends from a corresponding one of the bumps 80 to a corresponding one of the electroplated layers 12.

The metallic layers 5 are plated with plastic plating, electrolyzed plating, or the like in compliance with material of the bump-forming layer 8.

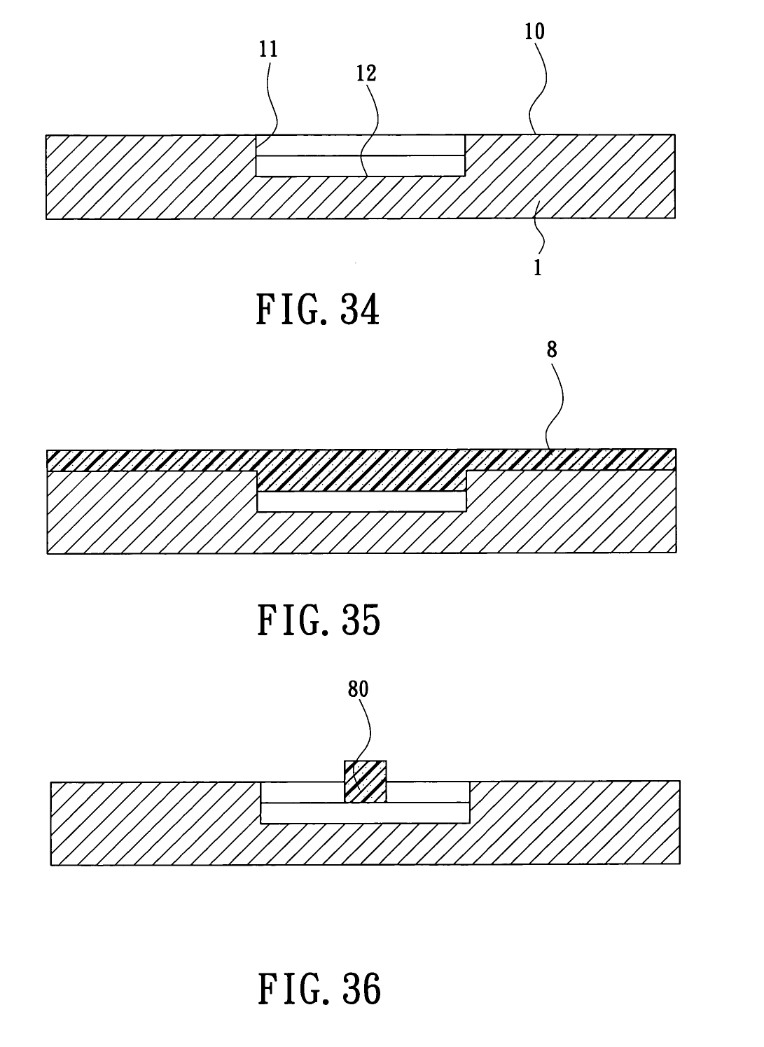

FIGS. 34 to 38 are cross-sectional views illustrating a sixth method according to the present invention to show a bump formed on a device having a semiconductor die.

Referring to FIG. 34, a semiconductor die 1 is provided first. The semiconductor die 1 has a pad-mounting surface 10 and a plurality of bonding pads 11 disposed on the pad-mounting surface 10. FIG. 34 shows only a single bonding pad 11. Each of the bonding pads 11 has an electroplated layer 12 formed thereon by plating.

A bump-forming layer 8 is formed on the pad-mounting surface 10 of the semiconductor die 1 as illustrated in FIG. 35. The bump-forming layer 8 is made of photoresist material or photoresist material having low-valence metallic powders having at least one of gold, silver, copper, iron, or aluminum powders, plastic material, or graphite material contained therein.

The bump-forming layer 8 is patterned and etched so as to form a plurality of bumps 80 on respective electroplated layers 12, as shown in FIG. 36.

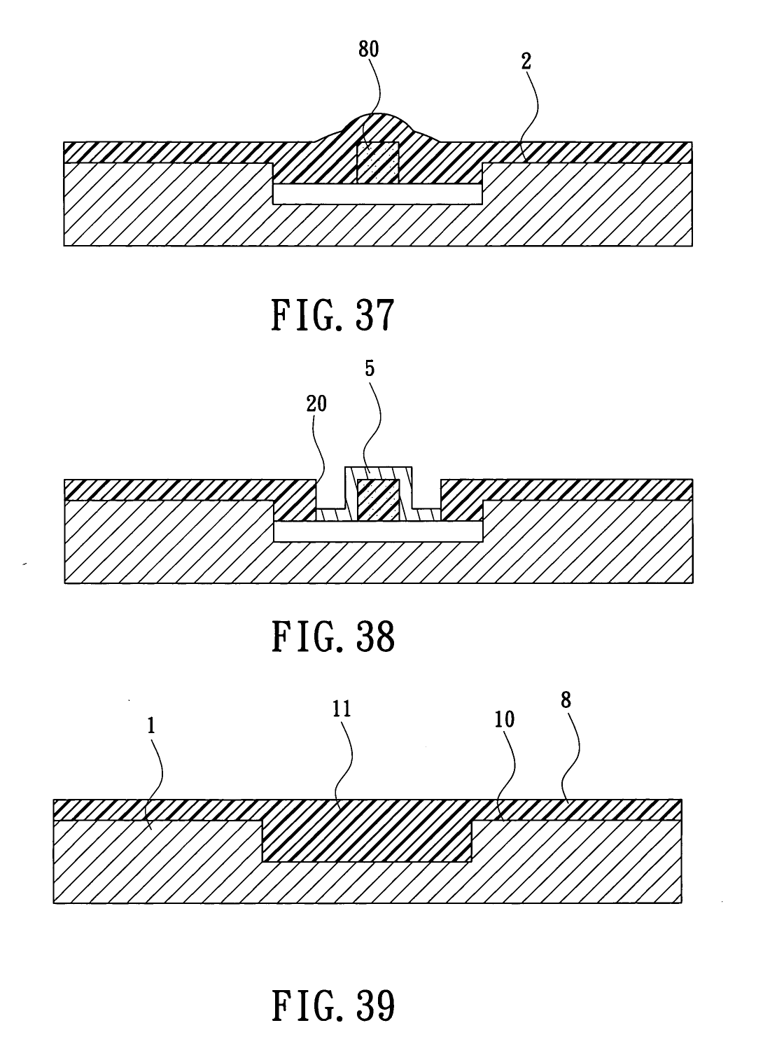

An insulation layer 2 is formed on the pad-mounting surface 10 of the semiconductor die 1 to hide the bumps 80 (in FIG. 37).

The insulation layer 2 is patterned and etched so as to form a plurality of through holes 20 for exposing the respective bumps 80 (in FIG. 38).

Each of the bumps 80 is then plated with a metallic layer 5. The metallic layer 5 on each of the bumps extends from a respective one of the bumps 80 to a respective one of the electroplated layers 12.

FIGS. 39 to 42 are cross-sectional views illustrating a seventh method according to the present invention to show a bump formed on a device having a semiconductor die.

Referring to FIG. 39, a semiconductor die 1 is provided first. The semiconductor die 1 includes a pad-mounting surface 10 and a plurality of bonding pads 11 disposed on the pad-mounting surface 10. FIG. 39 shows only a single bonding pad 11.

A bump-forming layer 8 is form over the pad-mounting surface 10 of the semiconductor die 1 as illustrated in FIG. 39. The bump-forming layer 8 is made of photoresist material or photoresist material having low-valence metallic powders having at least one of gold, silver, copper, iron, or aluminum powders, plastic material, or graphite material contained therein.

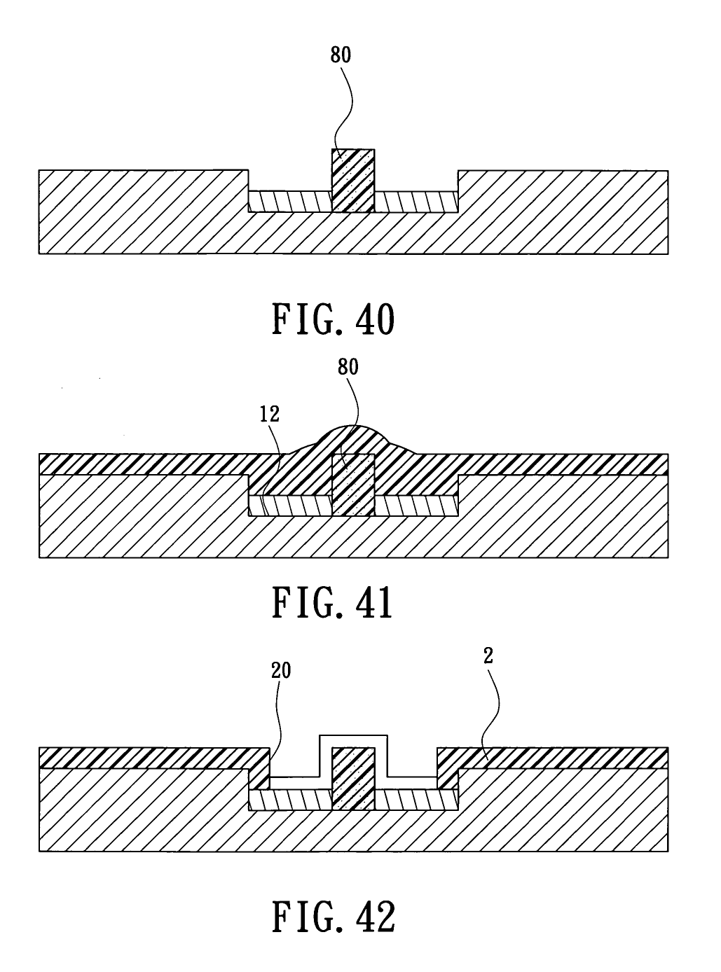

The bump-forming layer 8 is patterned and etched so as to form a plurality of bumps 80 on the respective bonding pads 12, see FIG. 40.

Each of the bonding pads 11 has an electroplated layer 12 formed by plating thereon except the portion on which the bump 80 is formed.

Referring to FIG. 41, an insulation layer 2 is formed over the pad-mounting surface 10 of the semiconductor die 1 to hide the bumps 80.

The insulation layer 2 is patterned and etched so as to form a plurality of through holes 20 for exposing the respective bumps 80 (see FIG. 42).

Each of the bumps 80 is plated with a metallic layer 5. The metallic layer 5 on each of the bumps 80 extends from a corresponding one of the bumps 80 to a corresponding one of the electroplated layers 12.

In particular, although the electroplated layers 12 in these embodiments are presented, the same result would be obtained in the absence of electroplated layer 12.

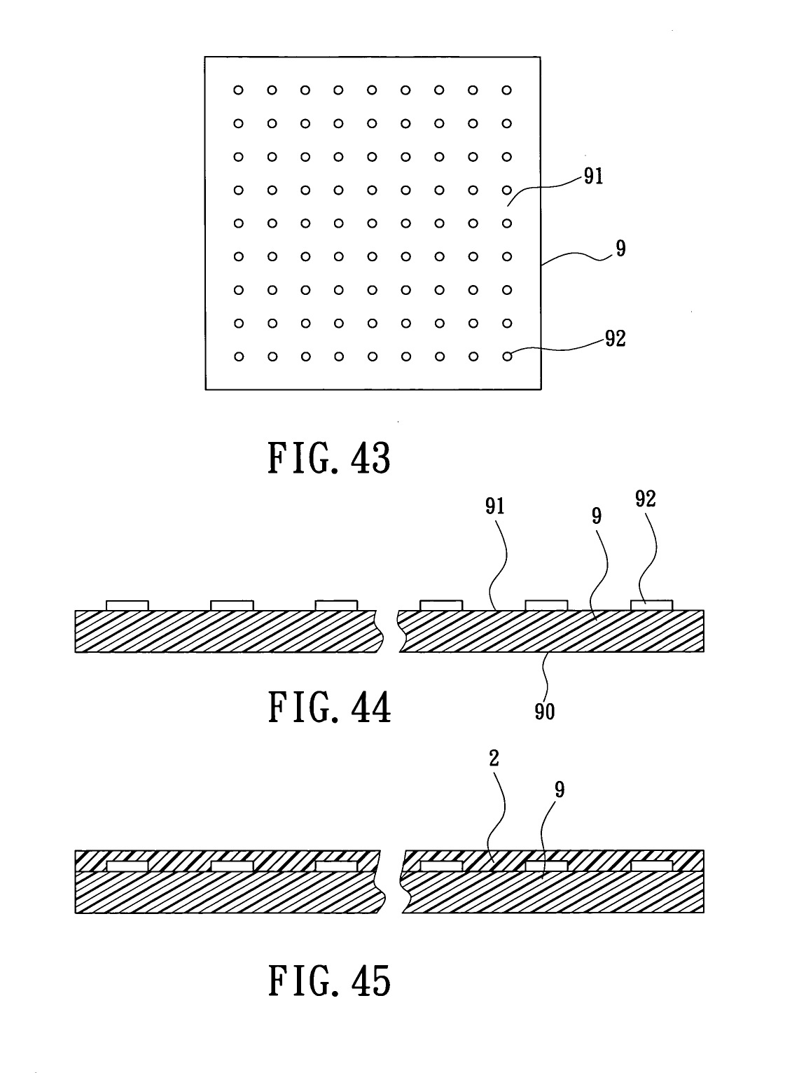

FIGS. 43 to 48 are cross-sectional views illustrating an eighth method according to the present invention to show a bump formed on a device having a BGA type semiconductor package substrate.

A package substrate 9 is provided first. The package substrate 9 has a die-mounting surface 90 on which a semiconductor die (not shown) is to be mounted, and a layout surface 91 opposite to the die-mounting surface 90 and having a plurality of contacts 92 arranged thereon in an array. The contacts 92 are connected electrically to the respective bonding pads of the semiconductor to be mounted on the die-mounting surface 90 via interconnections, plated through holes, etc (not shown).

An insulation layer 2 is formed on the layout surface 91 of the package substrate 9 (in FIG. 45).

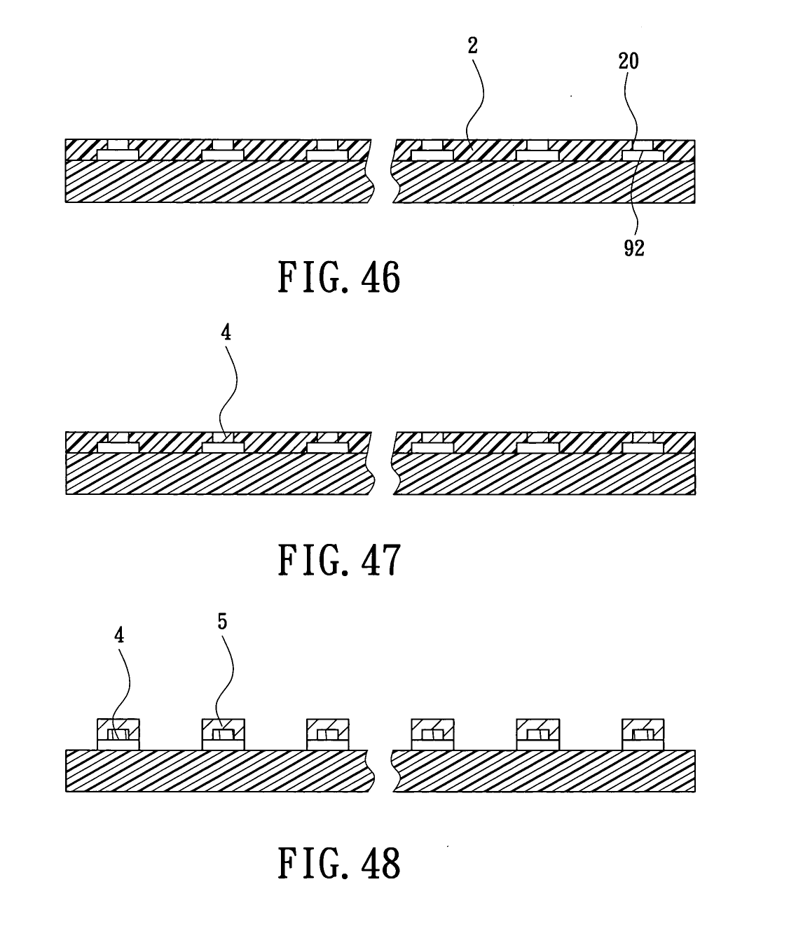

The insulation layer 2 is patterned and etched so as to form a plurality of through holes 20 for exposing the respective contacts 92 (in FIG. 46).

The through holes 20 are filled with bump-forming material therein so as to form a plurality of bumps 4 on the respective contacts 92 (in FIG. 47).

The bump-forming material is made of conductive pastes that have conductive metallic powders having at least one of gold, silver, copper, or aluminum powders. Alternatively, the bump-forming material is lead-free solder paste, or the bump-forming material is plastic.

The insulation layer 2 is then removed (in FIG. 48). Each of the bumps 4 is plated with a metallic layer 5. The metallic layer 5 on each of the bumps 4 extends from a corresponding one of the bumps 4 to a corresponding one of the contacts 92.

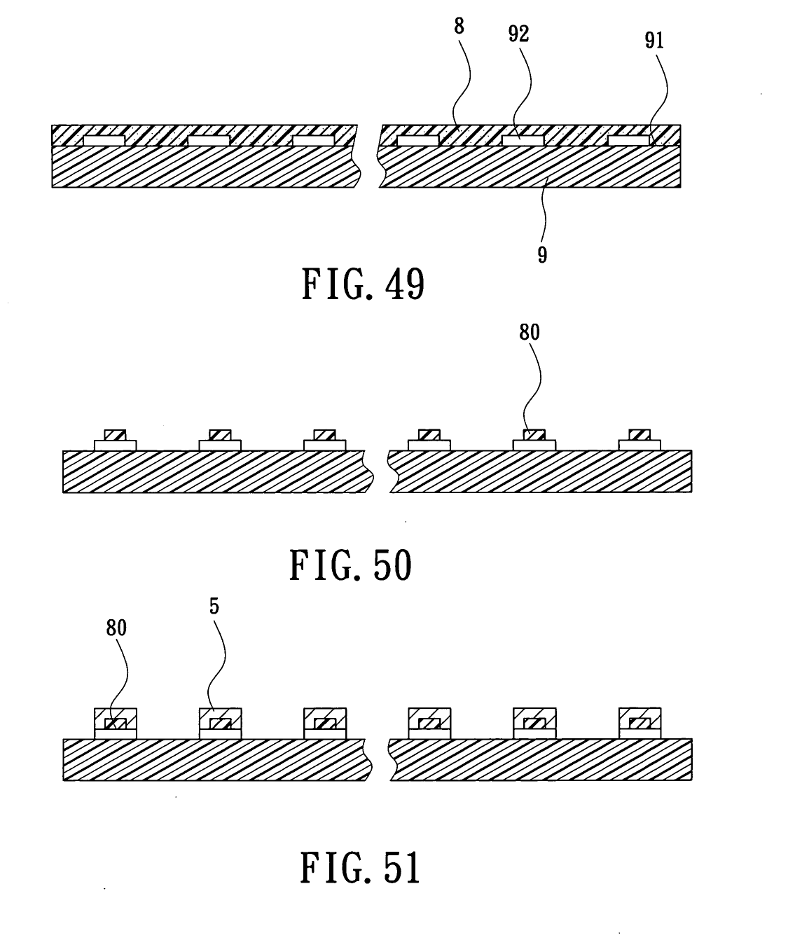

FIGS. 49 to 51 are cross-sectional views illustrating a ninth method according to the present invention to show a bump formed on a device having a BGA type semiconductor package substrate.

A package substrate 9, the same as in the eighth method, is provided first. The package substrate 9 has a die-mounting surface 90 on which a semiconductor die (not shown) is to be formed, and a layout surface 91 opposite to the die-mounting surface 90 and having a plurality of contacts 92 arranged thereon in an array. The contacts 92 are connected electrically to the respective bonding pads of the semiconductor die to be mounted on the die-mounting surface 90 via interconnections, plated through holes, etc (not shown).

A bump-forming layer 8 is formed over the layout surface 91 of the package substrate 9. The bump-forming layer 8 is made of photoresist material or photoresist material having low-valence metallic powders having at least one of gold, silver, copper, iron, or aluminum powders, plastic material, or graphite material contained therein.

The bump-forming layer 8 is patterned and etched so as to form a plurality of bumps 80 on the respective contacts 92 of the package substrate 9 (in FIG. 50).

Referring to FIG. 51, each of the bumps 80 is plated with a metallic layer 5. The metallic layer 5 on each of the bumps 80 extends from a corresponding one of the bumps 80 to a corresponding one of the contacts 92.

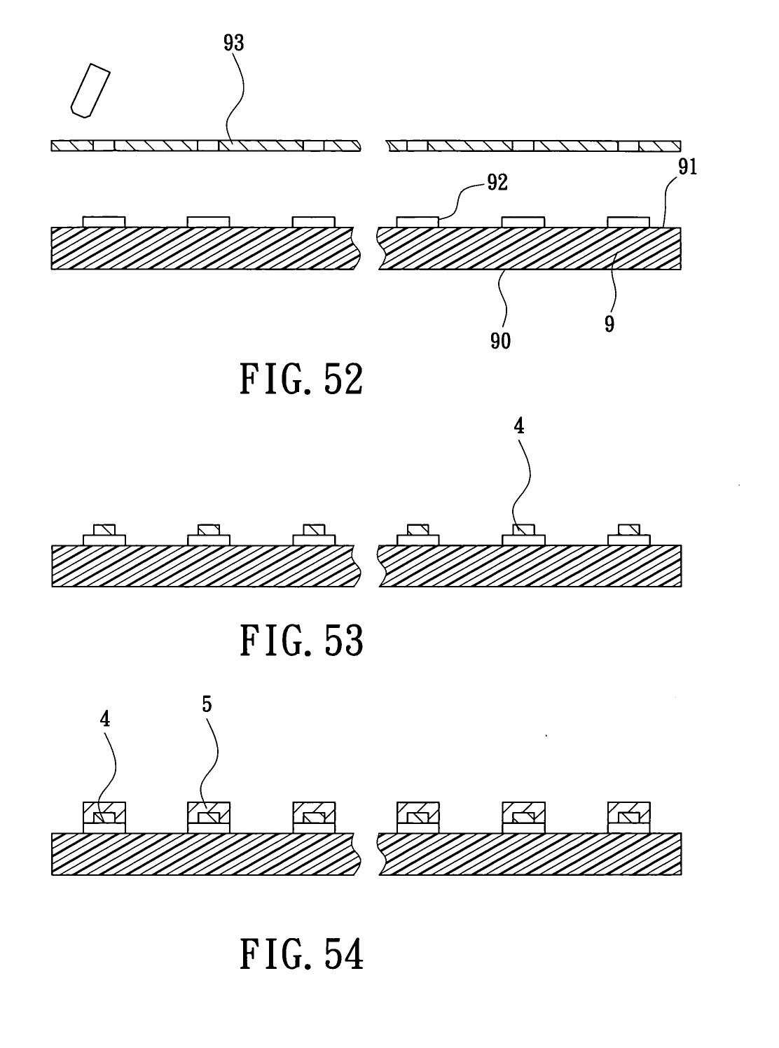

FIGS. 52 to 54 are cross-sectional views illustrating a tenth method according to the present invention to show a bump formed on a device having a BGA type semiconductor package substrate.

A package substrate 9, same as the eighth method, is provided first. The package substrate 9 has a die-mounting surface 90 on which a semiconductor die (not shown) is to be mounted, and a layout surface 91 opposite to the die-mounting surface 90 and having a plurality of contacts 92 arranged thereon in an array. The contacts 92 are connected electrically to the respective bonding pads of the semiconductor die to be-mounted on the dismounting surface 90 via interconnections, plated through holes, etc (not shown).

A plurality of bumps 4 formed from conductive pastes are provided on the contacts 92 of the package substrate 9, respectively, by a printing process using a stencil (in FIG. 53). Each of the bumps 4 is plated with a metallic layer 5. The metallic layer 5 on each of the bumps 4 extends from a corresponding one of the bumps to a corresponding one of the contacts 92 (in FIG. 54).

According to the embodiments mentioned above, the present invention provides a device including a semiconductor die 1 having a pad-mounting surface 10, a plurality of bonding pads 11 disposed on the pad-mounting surface 10, a plurality of bumps 4 formed on the respective bonding pads 11, and a plurality of metallic layers 5 each extending from a corresponding one of the bumps 4 to a corresponding one of the electroplated layers 12.

According to these embodiments mentioned above, the present invention provides a device including a package substrate 9 having a die-mounting surface 90 formed thereon, and a layout surface 91 opposite to the die-mounting surface 90 and having a plurality of contacts 92 arranged thereon in an array, a plurality of bumps formed on the respective contacts 92, and a plurality of metallic layers 5 each extending from a corresponding one of the bumps to a corresponding one of the contacts 92.

It should be apparent to those skilled in the art that the above description is only illustrative of specific embodiments and examples of the invention. The invention should therefore cover various modifications and variations made to the herein-described structure and operations of the invention, provided they fall within the scope of the invention as defined in the following appended claims.

What is claimed is:

1. A method for forming a conductive bump, comprising the steps of:
providing a semiconductor die with a pad-mounting surface and a plurality of bonding pads disposed on the pad-mounting surface;
covering the pad-mounting surface of the semiconductor die with an insulation layer made of photoresist material, patterning and etching the insulation layer so as to form a plurality of through holes for exposing respective the bonding pads;
forming a cover layer over the insulation layer to hide the through holes, patterning and etching the cover layer so as to form a plurality of exposure holes, which expose the respective bonding pads and which are smaller than the respective through holes;
filling the exposure holes with bump-forming material so as to form a plurality of bumps on the respective bonding pads; and
forming a plurality of metallic layers on the respective bumps after the cover layer is removed, each of the metallic layers extending from a corresponding one of the bumps to a corresponding one of the bonding pads.

2. The method as claimed in claim 1, further comprising the step of forming an electroplated layer on each of the bonding pads before the step of forming the insulation layer.

3. The method as claimed in claim 1, in the step of filling bump-forming material, the bump-forming material including conductive metallic powders having at least one of gold, silver, copper, aluminum powder, etc.

4. The method as claimed in claim 1, in the step of filling bump-forming material, the bump-forming material being lead-free solder paste.

5. The method as claimed in claim 1, in the step of filling bump-forming material, the bump-forming material being plastic.

6. A method for forming a conductive bump, comprising the steps of:
providing a semiconductor die having a pad-mounting surface and a plurality of bonding pads disposed on the pad-mounting surface;
covering an insulation layer made of photoresist material on the pad-mounting surface of a semiconductor die, patterning and etching the insulation layer so as to form a plurality of through holes for exposing the respective bonding pads;
forming a plurality of photoresist layers in the respective through holes and at a same height as the insulation layer, patterning and etching the photoresist layers so as to form a plurality of exposure holes for exposing the respective bonding pads, wherein the exposure holes are smaller than the through holes, respectively;
filling the exposure holes of the photoresist layers with bump-forming material so as to form a plurality of bumps on the respective bonding pads; and
forming a plurality of metallic layers on the respective bumps after the photoresist layers are removed, each of the plurality of metallic layers extending from a corresponding one of the bumps to a corresponding one of the bonding pads.

7. The method as claimed in claim 6, further comprising a step of forming an electroplated layer on each of the bonding pads before the step of forming an insulation layer.

8. The method as claimed in claim 6, further comprising a step of removing the insulation layer after the steps of removing the photoresist layers and forming the metallic layers.

9. The method as claimed in claim 6, in the step of filling bump-forming material, the bump-forming material including conductive metallic powders having at least one of gold, silver, copper or aluminum powder.

10. The method as claimed in claim 6, in the step of filling bump-forming material, the bump-forming material being lead-free solder paste.

11. The method as claimed in claim 6, in the step of filling bump-forming material, the bump-forming material being plastic.

12. A method for forming a conductive bump, comprising the steps of:
providing a semiconductor die having a pad-mounting surface and a plurality of bonding pads disposed on the pad-mounting surface;
covering the pad-mounting surface of the semiconductor die with an insulation layer made of photoresist material, patterning and etching the insulation layer so as to form a plurality of through holes for exposing the respective bonding pads;
filling the through holes of the insulation layer with bump-forming material so as to form a plurality of bumps on the respective bonding pads;
removing the insulation layer;
forming a cover layer on the pad-mounting surface of the semiconductor die with photoresist material to hide the bumps on the bonding pads, patterning and etching the cover layer so as to form a plurality of openings for exposing the respective bumps; and
forming a plurality of metallic layers on the respective bumps, each of the plurality of metallic layers extending from a corresponding one of the bumps to a corresponding one of the bonding pads.

13. The method as claimed in claim 12, further comprising the step of forming an electroplated layer on each of the bonding pads before the step of forming the insulation layer.

14. The method as claimed in claim 12, in the step of filling bump-forming material, the bump-forming material including conductive metallic powders having at least one of gold, silver, copper or aluminum powder.

15. The method as claimed in claim 12, in the step of filling bump-forming material, the bump-forming material including lead-free solder paste.

16. The method as claimed in claim 12, in the step of filling bump-forming material, the bump-forming material includes plastic.

17. A method for forming a conductive bump, comprising the steps of:
providing a semiconductor die having a pad-mounting surface and a plurality of bonding pads disposed on the pad-mounting surface;
covering the pad-mounting surface of the semiconductor die with an insulation layer made of photoresist material, patterning and etching the insulation layer so as to form a plurality of through holes for exposing the respective bonding pads;
filling the through holes of the insulation layer with bump-forming material to form a plurality of bumps on the respective bonding pads;
removing the insulation layer; and
forming a plurality of metallic layers on the respective bumps, each of the metallic layers extending from a corresponding one of the bumps to a corresponding one of the bonding pads.

18. The method as claimed in claim 17, further comprising a step of forming an electroplated layer on each of the bonding pads before the step of forming the insulation layer.

19. The method as claimed in claim 17, in the step of filling bump-forming material, the bump-forming material including conductive metallic powders having at least one of gold, silver, copper or aluminum powder.

20. The method as claimed in claim 17, in the step of filling bump-forming material, the bump-forming material includes lead-free solder paste.

21. The method as claimed in claim 17, in the step of filling bump-forming material, the bump-forming material includes plastic.

22. A method for forming a conductive bump, comprising the steps of:
providing a semiconductor die having a pad-mounting surface and a plurality of bonding pads disposed on the pad-mounting surface;
covering the pad-mounting surface of the semiconductor die with a bump-forming layer made of photoresist material, patterning and etching the bump-forming layer so as to form a plurality of bumps on the respective bonding pads; and
forming a plurality of metallic layers on the respective bumps, each of the metallic layers extending from a corresponding one of the bumps to a corresponding one of the bonding pads.

23. The method as claimed in claim 22, further comprising a step of forming an electroplated layer on each of the bonding pads before the step of forming the bump-forming layer.

24. The method as claimed in claim 23, in the step of forming the bump-forming layer, the bump-forming layer being made of photoresist material or photoresist material with low-valence metallic powders having at least one of gold, silver, copper, iron, or aluminum powder, plastic material, or graphite material contained therein.

25. The method as claimed in claim 23, in the step of forming the bump-forming layer, the metallic layers being plated by plastic plating, electrolyzed plating or a similar process in compliance with a material of the bump-forming layer.

26. The method as claimed in claim 22, further comprising steps of forming an insulation layer made of photoresist material to cover the pad-mounting surface and hide the bumps, and patterning and etching the insulation layer so as to form a plurality of through holes for exposing the respective bumps before the step of forming the metallic layers.

27. A method for forming a conductive bump, comprising the steps of:
providing a package substrate having a die-mounting surface, and a layout surface opposite to the die-mounting surface and having a plurality of contacts arranged on the die-mounting surface in an array, the contacts connected electrically to the respective bonding pads of the semiconductor die to be mounted on the die-mounting surface;
forming an insulation layer made of photoresist material on the layout surface of package substrate, patterning and etching the insulation layer so as to form a plurality of through holes for exposing the respective contacts;
filling the through holes of the insulation layer with bump-forming material so as to form a plurality of bumps on the respective contacts; and
forming a plurality of metallic layers on the respective bumps after the insulation layer is removed, each of the metallic layers extending from a corresponding one of the bumps to a corresponding one of the contacts.

28. The method as claimed in claim 27, in the step of filling bump-forming material, the bump-forming material being made of conductive pastes having conductive metallic powders having at least one of gold, silver, copper, or aluminum powder.

29. The method as claimed in claim 27, in the step of filling bump-forming material, the bump-forming material being lead-free solder paste.

30. The method as claimed in claim 27, in the step of filling bump-forming material, the bump-forming material being plastic.

31. A method for forming a conductive bump, comprising the steps of:
providing a package substrate having a die-mounting surface, and a layout surface opposite to the die-mounting surface and having a plurality of contacts arranged on the die-mounting surface in an array, the contacts connected electrically to the respective bonding pads of the semiconductor die to be mounted on the die-mounting surface;
forming a bump-forming layer made of photoresist material on the layout surface of the package substrate, patterning and etching the bump-forming layer so as to form a plurality of bumps on the respective bonding pads; and
forming a plurality of metallic layers on the respective bumps, each of the metallic layers extending from a corresponding one of the bumps to a corresponding one of the contacts.

32. The method as claimed in claim 31, in the step of forming bump-forming layer, the bump-forming layer being made of photoresist material or photoresist material having low-valence metallic powders having at least one of gold, silver, copper, iron, or aluminum powders, plastic material, or graphite material contained therein.

33. The method as claimed in claim 31, in the step of forming metallic layers, the metallic layers being plated by plastic plating, electrolyzed plating or a similar process in compliance with a material of the bump-forming layer.

34. A method for forming a conductive bump, comprising:
providing a package substrate having a die-mounting surface, and a layout surface opposite to the die-mounting surface and having a plurality of contacts arranged on the die-mounting surface in an array, the contacts connected electrically to the respective bonding pads of the semiconductor die to be mounted on the die-mounting surface;
forming a plurality of bumps on the respective contacts of the package substrate by a printing process using a stencil; and
forming a plurality of metallic layers on the respective bumps, each of the metallic layers extending from a corresponding one of the bumps to a corresponding one of the contacts.

35. A device formed with a conductive bump, comprising:
a semiconductor die having a pad-mounting surface and a plurality of bonding pads disposed on the pad-mounting surface;
a plurality of bumps formed on the respective bonding pads; and
a plurality of metallic layers formed on the respective bumps, each of the metallic layers extending from a corresponding one of the bumps to a corresponding one of the bonding pads.

36. The device as claimed in claim 35, further comprising a plurality of electroplated layers formed on the respective bonding pads.

37. The device as claimed in claim 35, wherein the bumps are made of conductive paste having conductive metallic powders having at least one of gold, silver, or aluminum powder.

38. The device as claimed in claim 35, wherein the bumps are made of lead-free solder paste.

39. The device as claimed in claim 35, wherein the bumps are made of plastic material.

40. The device as claimed in claim 35, wherein the bumps are made of photoresist material.

41. The device as claimed in claim 35, wherein the bumps include low-valence metallic powders having at least one of gold, silver, copper, ion, or aluminum powders, plastic material, or graphite material contained therein.

42. The device as claimed in claim 35, further comprising an insulation layer which is formed on the die-mounting surface, and which is formed with a plurality of through holes for exposing the respective bumps.
